(19) United States
(12) Patent Application Publication
(10) Pub. No.: US 2008/0286923 A1
(43) Pub. Date: Nov. 20, 2008

(54) METHOD FOR FABRICATING FLASH MEMORY

(75) Inventor: Sung Jin KIM, Seoul (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 12/122,314

(22) Filed: May 16, 2008

(30) Foreign Application Priority Data
May 18, 2007 (KR) 10-2007-0048562

(51) Int. Cl. H01L 21/336

(52) U.S. Cl. 438/257; 257/E21.409

(57) ABSTRACT

A method for fabricating a flash memory device is disclosed that can improve the reliability of the device by counteracting against the generation of charge traps induced by interfacial damage of an oxide film during the formation of spacers. The method may comprise forming spacers comprised of an oxide film and a nitride film, nitriding an interface of the oxide film after removal of the nitride film; and forming a salicide film after formation of an insulating film on a sidewall of the nitrided oxide film.

### CROSS-REFERENCE TO RELATED APPLICATION

This application claims priority to Korean Application No. 10-2007-0048562, filed on May 18, 2007, which is incorporated herein by reference in its entirety.

### BACKGROUND

1. Field of the Invention

Embodiments of the present invention relate to methods for fabricating a semiconductor, and more particularly, to methods for fabricating a flash memory.

2. Background of the Invention

Flash memory is a type of PROM (Programmable Read-Only Memory) that may be used for electrically re-writing data. One type of flash memory, referred to as a Flash EEPROM, utilizes a single transistor that may be designed to perform both a program input function of EPROM (Erasable PROM) and an erasing function of EEPROM (Electrically Erasable PROM). The Flash EEPROM device combines advantages of EPROM (in which each memory cell is composed of a single transistor so that the area of the memory cell is small and data can be collectively erased through ultraviolet radiation) and advantages of EEPROM (in which data can be electrically erased, but each memory cell is composed of two transistors, which results in a larger memory cell area relative to EPROM). Since memory information is not erased even when a power source is turned off, such flash memory is referred to as non-volatile memory, differing from DRAM (Dynamic Random-Access Memory) SRAM (Static Random-Access Memory), or other volatile memories.

Flash memory can be classified according to a cell array scheme. Cell array schemes include a NOR type structure, where cells are arranged in parallel between a bit line and ground, and a NAND type structure, where cells are serially arranged between the bit line and ground. NOR-type flash memory, which has a parallel structure, has been widely used for booting a cellular phone because a high-speed random access is possible when performing a reading operation. NAND-type flash memory, which has a serial structure, is generally more suitable for storing data because, relative to NOR-type flash memory, a reading speed is slow but a writing speed is fast. NAND-type flash memory also has smaller cell size than NOR-type flash memory and is therefore generally more profitable for applications in which miniaturization is desirable. Further, flash memory may be classified as a stack gate type or a split gate type depending on the structure of a unit cell. Flash memory may also be classified as a floating gate type and a SONOS (Silicon-Oxide-Nitride-Oxide-Silicon) type, depending on the shape of an electric charge storage layer in the flash memory.

Hereinafter, one example of a typical flash memory device will be described with reference to the accompanying drawings.

FIG. 1 is a view illustrating a cross section of one example of a conventional flash memory cell. In this example, the flash memory cell may have a floating gate 104 for storing data and a control gate 108 for controlling the flow of current between a source junction 110 and a drain junction 112. The floating gate 104 may be completely isolated from an external electrode because it is isolated from the control gate 108 by a gate insulating film 106 and separated from a semiconductor substrate 100 by a tunnel oxide film 102.

Programming for the flash memory cell constructed as above may be done by injecting channel hot electrons into the floating gate 104, the channel hot electrons generated by applying a voltage of 0V to the drain junction 112, a high(+) voltage to the source junction 110, and an intermediate level voltage to the control gate 108. A cell erase operation may be done by application of 0V to the source junction 110 and a high(+) voltage to the control gate 108 so that the electrons of the floating gate 104 can be ejected toward the control gate 108 by use of electric fields concentrated at the corners of the floating gate 104.

FIG. 2 is a process sequence diagram illustrating one example of a typical process for forming a salicide film on the exemplary flash memory device of FIG. 1. Prior to the formation of the source/drain junctions 110 and 112, spacers 114 may be formed on the sidewalls of the control gate 108, the gate insulating film 106, and the floating gate 104. The spacers 114 may be formed on the sidewalls by sequentially depositing an oxide film, an HTO (High Temperature Oxide) film, a Tetra-ethyl ortho-silicate (TEOS) film, and a slot plane antenna (SPA) SiN film on the semiconductor substrate 100 where the control gate 108 is formed and then selectively etching the deposited films (S200, S202).

Next, the source/drain junctions 110 and 112 may be formed by performing an impurity ion implantation process, for example, an N-type impurity ion implantation process, on portions of the semiconductor substrate 100 exposed by the spacers 114 and the control gate 108 (S204).

Then, to provide a margin between the control gate 108 and a contact, a part of the spacers 114, for example, the SPA SiN film, may be removed by performing a phosphoric acid strip process (S206).

In the phosphoric acid strip process, the TEOS film, which is the outermost wall around the control gate 108, is exposed, and therefore the TEOS film, which is an oxide film, is at risk of being removed in a subsequent NSAL (Non-Salicide) process. To prevent the removal of the TEOS film, a SiN film of about 200 Å may be formed on the resultant material, including the exposed TEOS film (S208).

Next, a salicide film (not shown) may be formed on the surfaces of the source/drain junctions 110 and 112 and the control gate 108 by performing an NSAL process on the entire surface of the semiconductor substrate where the spacers 114 are formed (S210).

However, the phosphoric acid strip process for removing a part of the spacers 114 may damage the interface of the TEOS film (which is a part of the spacers 114) exposed by the phosphoric acid strip process. Damage to the interface of the TEOS film may cause a charge trap, i.e., electron charges on the floating gate 104 may get trapped in the oxide spacer film and the TEOS film. Deterioration of the TEOS film may also cause electron charges to be ejected.

Then, when a SiN film is re-deposited to prevent the removal of the TEOS film during the NSAL process, which follows the phosphoric acid strip process, a space may be formed between the TEOS film and the SiN film due to an interfacial stress between the TEOS film and the SiN film. The space may cause the TEOS film to be exposed to the outside, which may lead to a more serious charge trapping due to damage to the TEOS film during the NSAL process.

### SUMMARY OF SOME EXAMPLE EMBODIMENTS

In general, example embodiments of the invention relate to a method for fabricating a flash memory device that can prevent or at least counteract against electron charges on a floating gate being ejected or being trapped in a TEOS film. Example embodiments may include nitriding the interface of the TEOS film exposed after the removal of a nitride spacer film.

One embodiment relates to a method for fabricating a flash memory device comprising the steps of: forming a floating gate, a gate insulating film, and a control gate on a semiconductor substrate; forming spacers comprised of an oxide film and a nitride film on the floating gate, the gate insulating film, and the control gate by sequentially depositing and etching the oxide and nitride films on the semiconductor substrate; forming source/drain junctions by performing an impurity ion implantation process; nitriding an interface of the oxide film after removal of the nitride film; and forming a salicide film on the surfaces of the source/drain junctions and the control gate after the formation of an insulating film on a sidewall of the nitrided oxide film.

An example method for fabricating a flash memory device may further comprise the step of nitriding the interface of the oxide film by performing a nitriding process on the semiconductor substrate where the insulating film is formed before the salicide film is formed.

The nitriding process of the interface of the oxide spacer film and/or the nitriding process of the semiconductor substrate where the insulating film is formed may be performed by a nitrogen plasma process.

The nitrogen plasma process(es) may be performed for 70 to 200 seconds at a bias voltage of 200 to 400 W.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

Additional features will be set forth in the description which follows, and in part will be obvious from the description, or may be learned by the practice of the teachings herein. Features of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

Aspects of example embodiments of the invention will become apparent from the following description of example embodiments given in conjunction with the accompanying drawings, in which:

FIG. 1 is a view illustrating a cross section of one example of a conventional flash memory cell;

FIG. 2 is a process sequence diagram illustrating one example of a typical process for forming a salicide film on the exemplary flash memory device of FIG. 1; and

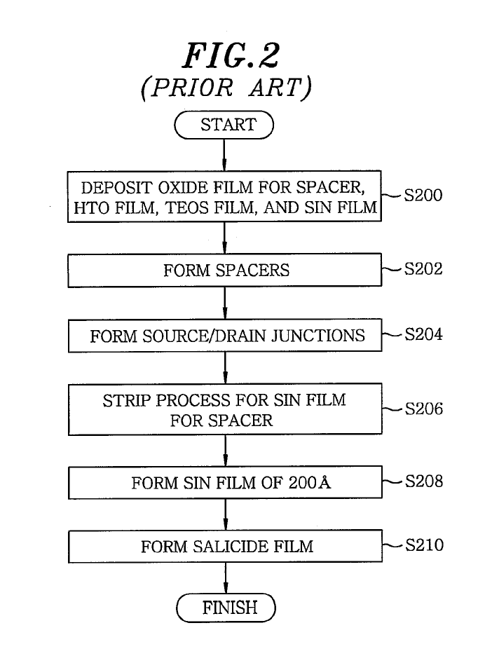

FIG. 3 is a process sequence diagram illustrating a process for forming a salicide film of a flash memory device according to an embodiment of the present invention.

### DETAILED DESCRIPTION OF SOME EXAMPLE EMBODIMENTS

Hereinafter, specific embodiments of a process for forming a salicide film of a flash memory are be described in detail with reference to the accompanying drawings. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

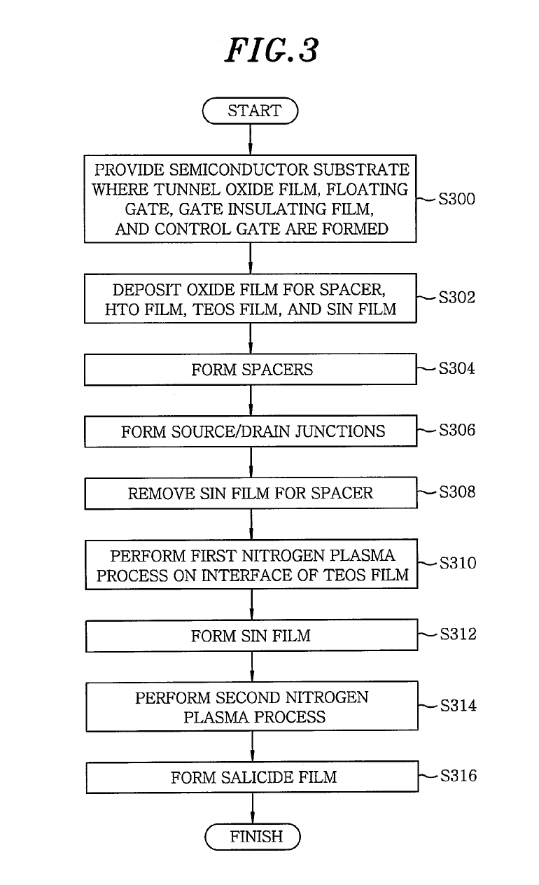

FIG. 3 is a process sequence diagram illustrating an embodiment of a process for forming a salicide film of a flash memory device.

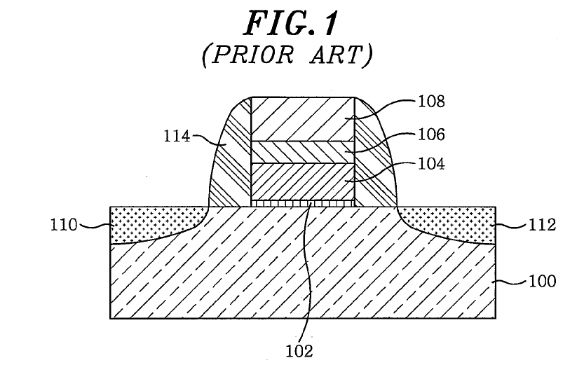

Referring to FIGS. 1 and 3, a tunnel oxide film 102, a floating gate 104, a gate insulating film 106, and a control gate 108 may be formed on a semiconductor substrate 100 (S300). The floating gate 104 may be completely isolated from an external electrode because it is isolated from the control gate 108 by the gate insulating film 106 and is separated from the semiconductor substrate 100 by the tunnel oxide film 102.

Next, in order to form spacers 114 on the sidewalls of the control gate 108, the gate insulating film 106, and the floating gate 104, oxide and nitride films may be sequentially deposited on the semiconductor substrate 100 where the control gate 108 is formed. The oxide film may include a plurality of films, for example, an inner oxide film having a thickness of 60 Å thickness, an HTO film having a thickness of 75 Å, and a TEOS film having a thickness of 200 Å. The nitride film may include an SiN film having a thickness of about 770 Å, which may be deposited by an SPA method.

Thereafter, spacers 114 may be formed on the sidewalls of the control gate 108, the gate insulating film 106, and the floating gate 104 by selectively etching the inner oxide film, the HTO film, the TEOS film, and the SiN film deposited on the semiconductor substrate 100 (S304).

Next, source/drain junctions 110 and 112 may be formed by performing a PEP (Photo Etching Process) for an impurity ion implantation process and then performing an impurity ion implantation process, for example, an N-type impurity ion implantation process (S306).

Then, the SiN film having a thickness of 770 Å, i.e., the nitride film, may be removed by performing strip and cleaning processes (S308). With the removal of the SiN film, the interface of the TEOS film is at risk of being damaged as the TEOS film is exposed to the outside.

To counteract the risk of damage to the interface of the TEOS film, the interface of the TEOS film may be nitrided by performing a nitrogen plasma process on the resultant material (S310). That is, the interface of the TEOS film may be nitrided by inserting N into the interface of the TEOS film by a nitrogen plasma process.

The nitrogen plasma process in the step S310 may be performed for 70 to 200 seconds at a bias voltage of, for example, 200 to 400 W.

Preventing interfacial damage by nitriding the interface of the TEOS film by a nitrogen plasma process serves to counteract against electron charges on the floating gate 104 being ejected or being trapped in the oxide film or in the TEOS film.

After the step S310, an SiN film having a thickness of about 200 Å may be formed by deposition and etching processes on a sidewall of the nitrided TEOS film (S312). In the formation of the SiN film, a slight space can often form between the TEOS film and the SiN film due to stress between the TEOS film and the SiN film. Accordingly, in a subsequent NSAL process, the TEOS film may be damaged through the slight space and, thus, a charge trap may be generated.

In order to counteract against such a charge trap, nitrogen ions may again be inserted into the interface of the TEOS film through the space between the SiN film and the TEOS film by performing a second nitrogen plasma process on the entire surface of the semiconductor substrate 100 where the SiN film is formed (S314).

Thereafter, a salicide film may be formed on the control gate 108 and the source/drain junctions 110 and 112 by performing an NSAL process (S316).

The first and second nitrogen plasma processes in the steps S310 and S314 may be performed for 70 to 200 seconds at a bias voltage of, for example, 200 to 400 W.

Although the above method has been described with respect to an example in which the second nitrogen plasma process is performed after the formation of an SiN film on the sidewall of the nitrided TEOS film, the second nitrogen plasma process may optionally be omitted.

The present invention is not limited to the above-described specific embodiments, and those skilled in the art to which the present invention pertains will appreciate that various modifications are possible without departing from the scope of the present invention as defined in the following claims. Furthermore, such modifications fall within the range of the description of the claims.

As described above, example embodiments can counteract against a charge trap or ejection and thus improve the reliability of the device by nitriding the interface of the TEOS film exposed after the removal of the nitride film.

Furthermore, example embodiments can counteract against a charge trap caused by interfacial stress between the TEOS film and the SiN film and thus improve the reliability of the device by nitriding the interface of the TEOS film exposed to the outside by the removal of the nitride film and nitriding the interface of the TEOS film a second time after the formation of an insulating film on the sidewall of the TEOS film.

What is claimed is:

1. A method for fabricating a flash memory device, comprising the steps of:
forming a floating gate, a gate insulating film, and a control gate on a semiconductor substrate;
forming spacers comprised of an oxide film and a nitride film on the floating gate, the gate insulating film, and the control gate by sequentially depositing and etching the oxide and nitride films on the semiconductor substrate;
forming source/drain junctions by performing an impurity ion implantation process;
nitriding an interface of the oxide film after removal of the nitride film; and
forming a salicide film on the surfaces of the source/drain junctions and the control gate after formation of an insulating film on a sidewall of the nitrided oxide film.

2. The method of claim 1, wherein the nitriding of the interface of the oxide film is performed by a first nitrogen plasma process.

3. The method of claim 2, wherein the first nitrogen plasma process is performed for 70 to 200 seconds at a bias voltage of 200 to 400 W.

4. The method of claim 1, further comprising the step of nitriding the interface of the oxide film after the formation of the insulating film on the sidewall of the nitrided oxide film and before formation of the salicide film by performing a nitriding process on the semiconductor substrate where the insulating film is formed.

5. The method of claim 4, wherein the nitriding process is performed by a second nitrogen plasma process.

6. The method of claim 5, wherein the second nitrogen plasma process is performed for 70 to 200 seconds at a bias voltage of 200 to 400 W.
